(19) United States
(12) Patent Application Publication
(10) Pub. No.: US 2022/0163415 A1
(43) Pub. Date: May 26, 2022

(54) Piezosensitive Sensor Having Criss-Crossed Electrodes

(71) Applicant: UNIVERSAL CEMENT CORPORATION, Taipei (TW)

(72) Inventors: Shao-Chuan Fang, Taitung County (TW); Chih-Sheng Hou, Taipei City (TW)

(21) Appl. No.: 17/102,460

(22) Filed: Nov. 24, 2020

(51) Int. Cl. G01L 1/16; G01L 1/18; H01L 41/047

(52) U.S. Cl. CPC G01L 1/16; G01L 1/18; H01L 41/0475; H01L 41/0472; H01L 41/0471

(57) ABSTRACT

A piezosensitive sensor includes a first substrate, a second substrate, a first electrode formed on the first substrate, a second electrode formed on the second substrate, and a sensor array. The sensor array includes a plurality of sensing pixels arranged in rows and columns, each sensing pixel of the plurality of sensing pixels includes a piezosensitive element formed between the first electrode and the second electrode for generating an electrical parameter dependent upon a force applied thereto. A sensing pixel of the plurality of sensing pixels is coupled to an upper sensing pixel, a lower sensing pixel, a left sensing pixel and a right sensing pixel via the first electrode and the second electrode in an up direction, a down direction, a left direction and a right direction, respectively.

### BACKGROUND OF THE INVENTION

### 1. Field of the Invention

The invention relates to sensor technology, and in particular, to a piezosensitive sensor having criss-crossed electrodes.

### 2. Description of the Prior Art

Pressure sensors or force sensors are devices for measuring a force, and have found wide applications in home, commercial and industrial uses. In order to meet requirements of various applications, the pressure sensors are frequently required to be trimmed or cropped into suitable shapes. In the related art, the pressure sensors are made of a matrix of sensing pixels only connected at the boundary regions of the pressure sensors to obtain the measurements taken by the pressure sensors. As a consequence, any trimming or cropping must include the boundary regions, imposing limits on design flexibility.

### SUMMARY OF THE INVENTION

According to one embodiment of the invention, a piezosensitive sensor includes a first substrate, a second substrate, a first electrode formed on the first substrate, a second electrode formed on the second substrate, and a sensor array. The sensor array includes a plurality of sensing pixels arranged in rows and columns, each sensing pixel of the plurality of sensing pixels includes a piezosensitive element formed between the first electrode and the second electrode and configured to generate an electrical parameter dependent upon a force applied thereto. A sensing pixel of the plurality of sensing pixels is coupled to an upper sensing pixel, a lower sensing pixel, a left sensing pixel and a right sensing pixel via the first electrode and the second electrode in an up direction, a down direction, a left direction and a right direction, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is schematic view of a piezosensitive sensor according to an embodiment of the invention.

FIG. 2 is a cross-sectional view of a sensing pixel along a line 2-2′ in FIG. 1.

FIG. 3 is a schematic view of a sensing pixel in FIG. 1.

FIG. 4 is schematic view of a cropped piezosensitive sensor according to an embodiment of the invention.

FIG. 5 is schematic view of a cropped piezosensitive sensor according to another embodiment of the invention.

FIG. 6 is a schematic view of a piezosensitive sensor in the related art.

FIG. 7 is a schematic view of another piezosensitive sensor in the related art.

### DETAILED DESCRIPTION

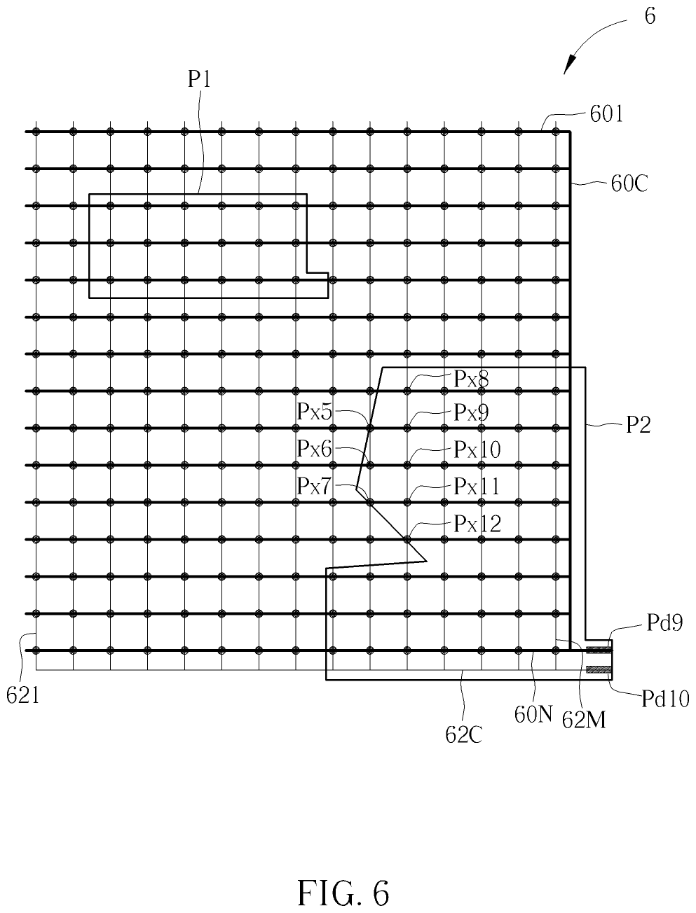

FIG. 6 is a schematic view of a piezosensitive sensor 6 in the related art. The piezosensitive sensor 6 may include top electrodes 601 to 60N and a common top electrode 60C on a top substrate, bottom electrodes 621 to 62M and a common bottom electrode 62C on a bottom substrate, a sensor array including a plurality of sensing pixels, an top sensing pad Pd9 and a bottom sensing pad Pd10, N, M being integers exceeding 1 and N, M may be identical to or different from each other. The top electrodes 601 to 60N are arranged along a vertical direction and in parallel to each other, and are coupled to the top sensing pad Pd9 via the common top electrode 60C. The bottom electrodes 621 to 62M are arranged along a horizontal direction and in parallel to each other, and are coupled to the bottom sensing pad Pd10 via the common bottom electrode 62C. The sensor array is arranged between the top substrate and the bottom substrate, and each sensing pixel in the sensor array is arranged at a crossing point of a top electrode 60n and a bottom electrode 62m, n being an integer between 1 and N, m being an integer between 1 and M.

Since the top sensing pad Pd9 and the bottom sensing pad Pd10 are only available at the right bottom corner, the common top electrode 60C is only available at the rightmost column and the common bottom electrode 62C is only available at the bottommost row, a sensor patch must be cropped from the right bottom portion of the piezosensitive sensor 6 and in a rectangular or square shape in order to function properly. For example, a sensor patch P1 cropped from the central portion of the piezosensitive sensor 6 may not be functional since top electrodes 603 to 605 are disconnected from the common top electrode 60C and the top sensing pad Pd9, bottom electrodes 623 to 628 are disconnected from the common bottom electrode 62C and the bottom sensing pad Pd10, any sensing signal picked up by the sensing pixels in the sensor patch P1 may not be read. In another example, a sensor patch P2 cropped from the right bottom portion of the piezosensitive sensor 6 may be functional in a limited manner owing to the irregular cropping shape, and sensing pixels Px5 to Px12 are not functional since they are disconnected from the common top electrode 60C, the top sensing pad Pd9, b the common bottom electrode 62C and the bottom sensing pad Pd10.

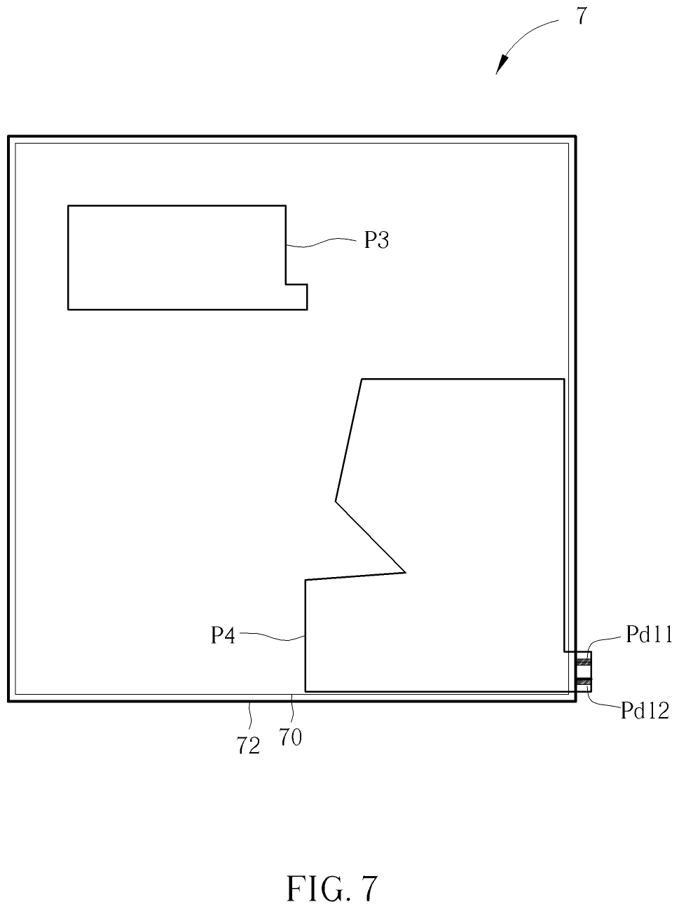

FIG. 7 is a schematic view of another piezosensitive sensor in the related art. The piezosensitive sensor 7 may include a top electrode sheet 70 on a top substrate, a bottom electrode sheet 72 on a bottom substrate, a sensor array including a plurality of sensing pixels, an top sensing pad Pd11 and a bottom sensing pad Pd12. Since the top sensing pad Pd10 and the bottom sensing pad Pd12 are only available at the right bottom corner, a sensor patch must be cropped from the right bottom portion of the piezosensitive sensor 7 in order to function properly. For example, a sensor patch P3 cropped from the central portion of the piezosensitive sensor 7 may not be functional since no sensing pad is available for reading a sensing signal. In another example, a sensor patch P4 cropped from the right bottom portion of the piezosensitive sensor 7 may be functional since the cropping area includes the top sensing pad Pd11 and the bottom sensing pad Pd12.

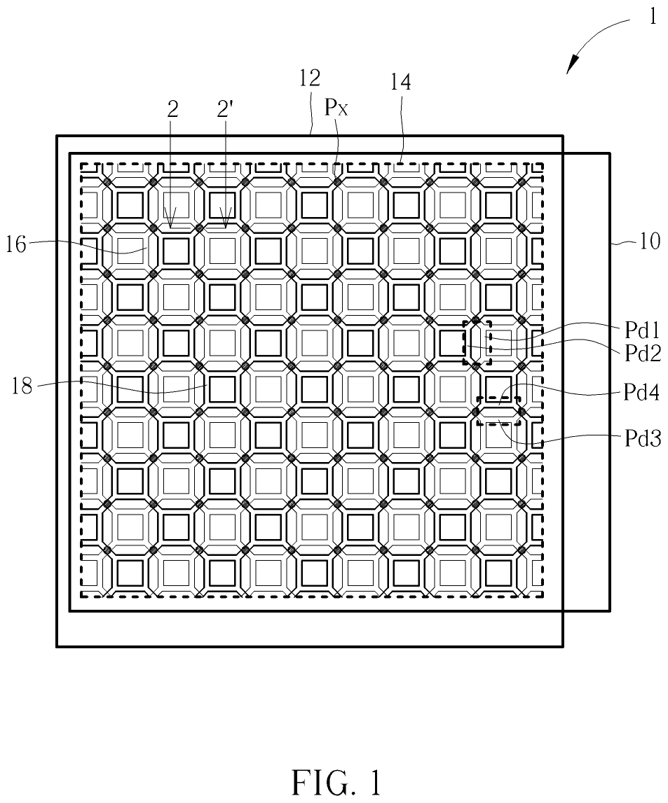

FIG. 1 is schematic view of a piezosensitive sensor 1 according to an embodiment of the invention. The piezosensitive sensor 1 may be cropped into suitable shapes and sizes to accommodate for a variety of applications, and may be used to detect a force applied thereon. The piezosensitive sensor 1 may be used to provide anti-collision between automobiles, ships and other vehicles and to provide industrial safety for robotic arms and other industrial machineries.

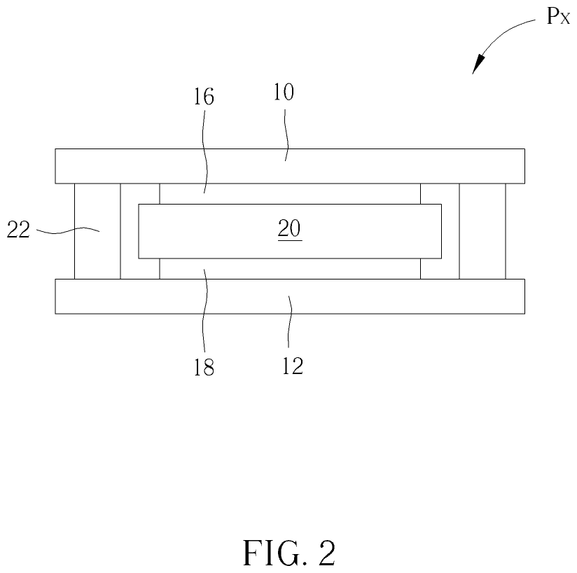

FIG. 2 is a cross-sectional view of the sensing pixel Px along a line 2-2′ in FIG. 1. The piezosensitive sensor 1 may include a first substrate 10, a second substrate 12, a first electrode 16 formed on the first substrate 10, a second electrode 18 formed on the second substrate 12 and criss-crossed with the first electrode 16, and a sensor array 14. The first electrode 16 and the second electrode 18 are spaced apart from each other. The sensor array 14 may include a plurality of sensing pixels Px arranged in rows and columns and disposed between the first electrode 16 and the second electrode 18. The first substrate 10 may be the top substrate, and the second substrate 12 may be the bottom substrate arranged below the first substrate 10. The first electrode 16 may be the top electrode, and the second electrode 18 may be the bottom electrode.

Since the first electrode 16 is criss-crossed with the second electrode 18, no insulation is required between the first electrode 16 and the second electrode 18, reducing manufacturing costs.

Each sensing pixel Px may include a piezosensitive element 20 and adhesion 22 formed between the first electrode 16 and the second electrode 18. The piezosensitive element 20 may be made of a piezoelectric material, a piezoresistive material, a piezo-capacitive material or a piezo-inductive material. The first surface may be the top surface of the piezosensitive element 20, and the second surface may be the bottom surface of the piezosensitive element 20. The first surface of the piezosensitive element 20 may be coupled to the first electrode 16, and the second surface of the piezosensitive element 20 may be coupled to the second electrode 18. In some embodiments, the first surface of the piezosensitive element 20 may be in contact with the first electrode 16, and second surface of the piezosensitive element 20 may be in contact with the second electrode 18. When the piezosensitive element 20 is the piezoelectric material, the piezosensitive element 20 may generate an electrical parameter between the first surface and the second surface upon a force being applied to the first surface and/or the second surface. The electrical parameter may be proportional to the force applied, and may be a voltage signal or a current signal. The electrical parameter on the first surface of the piezosensitive element 20 and the electrical parameter on the second surface of the piezosensitive element 20 may be transmitted via the first electrode 16 and the second electrode 18 to a controller, respectively. When the force exerted on the sensing pixel Px varies, the electrical parameters of the first electrode 16 and the second electrode 18 are changed accordingly to indicate the change of the force. The controller may determine the force applied to the sensor array 14 according to a difference between the electrical parameter of the first electrode 16 and the electrical parameter of the second electrode 18. The adhesion 22 may adhere the first electrode 16 and the second electrode 18.

In a similar manner, when the piezosensitive element 20 is the piezoresistive material, the piezosensitive element 20 may change in resistance upon being pressed, and the controller may determine the force based on change in the resistance according to the signal on the first electrode 16 and the signal on the second electrode 18. When the piezosensitive element 20 is the piezo-capacitive material, the piezosensitive element 20 may change in capacitance upon being pressed, and the controller may determine the force based on change in the capacitance according to the signal on the first electrode 16 and the signal on the second electrode 18. When the piezosensitive element 20 is the piezo-inductive material, the piezosensitive element 20 may change in inductance upon being pressed, and the controller may determine the force based on change in the inductance according to the signal on the first electrode 16 and the signal on the second electrode 18.

Referring to FIG. 1, the first electrode 16 and the second electrode 18 are meshed in structure, and the plurality of sensing pixels Px may be coupled to each other via the first electrode 16 and the second electrode 18. When any one of the plurality of sensing pixels Px experiences a force, electrical parameters on the first electrode 16 and the second electrode 18 will be generated to reflect the magnitude of the force. The electrical parameters may include, but are not limited to, resistance, conductivity, capacitance, or electric charges, or voltages. The meshed structure of the first electrode 16 and the second electrode 18 enables the electrical parameters thereon to be transmitted along 4 substantially orthogonal directions, enhancing signal connectivity and design flexibility. The 4 substantially orthogonal directions may be up, down, left and right. In a case where connections in 3-out-of-4 directions of a particular sensing pixel Px are removed or blocked in the cropping process to accommodate for a design requirement, the sensing pixel Px may remain active and detect a force exerted thereupon to generate the electrical parameter, and the electrical parameters on the first electrode 16 and the second electrode 18 may still be transmitted via the remaining connection of the sensing pixel Px and the meshed networks of the first electrode 16 and second electrode 18 to the controller. In this fashion, the design flexibility of the shape and dimensions of the piezosensitive sensor 1 may be enhanced while delivering the force detection. The first electrode 16 and the second electrode 18 may be shifted slightly away from each other to reduce interference. In some embodiments, the first electrode 16 and the second electrode 18 may be aligned with each other to reduce circuit layout complexity. The first electrode 16 and the second electrode 18 may be formed of a conductive material such as copper, copper alloys, gold, gold alloys, silver, silver alloys, platinum, platinum alloys, other metals and other alloys.

A segment of the first electrode 16 coupling between two adjacent sensing pixels Px may serve as a sensing pad to output the electrical parameter of the first electrode 16, and similarly, a segment of the second electrode 18 coupling between the two adjacent sensing pixels Px may be serve as another sensing pad to output the electrical parameter of the second electrode 18. For example, sensing pads Pd1 and Pd3 may output the electrical parameter of the first electrode 16 to the controller, and sensing pads Pd2 and Pd4 may output the electrical parameter of the second electrode 18 to the controller. The segment of the first electrode 16 and the segment of the second electrode 18 may be arranged in parallel and non-overlapping to each other. Further, a first crimp terminal may be attached to the segment of the first electrode 16 to access the electrical parameter of the first electrode 16, and a second crimp terminal may be attached to the segment of the second electrode 18 to access the electrical parameter of the second electrode 16. In some embodiments, the locations of the sensing pads for reading the electrical parameter of the first electrode 16 and the electrical parameter of the second electrode 18 may be adjacent to each other. For example, the sensing pad for reading the electrical parameter of the first electrode 16 may be the sensing pad Pd1, and the sensing pad for reading the electrical parameter of the second electrode 18 may be the sensing pad Pd2. In other embodiments, the locations of the sensing pads for reading the electrical parameter of the first electrode 16 and the electrical parameter of the second electrode 18 may be selected based on the design requirement and may not be adjacent to each other. For example, the sensing pad for reading the electrical parameter of the first electrode 16 may be the sensing pad Pd1, and the sensing pad for reading the electrical parameter of the second electrode 18 may be the sensing pad Pd4.

The first substrate 10 may support and secure the first electrode 16, and the second substrate 12 may support and secure the second electrode 18. The first substrate 10 and the second substrate 12 may be made of a rigid material, a flexible material or a combination thereof. The rigid material may be glass, a ceramic material, a silicon-based material, or other suitable rigid and electrically insolating materials. The flexible material may be silicone, urethane, polyurethane, polyimide, polyethylene terephthalate (PET), polyethylene naphthalate (PEN), polycarbonate (PC), or other suitable flexible and electrically insolating materials.

The piezosensitive sensor 1 employs the meshed structure of the first electrode 16 and the second electrode 18 to transmit electrical parameters thereon along 4 orthogonal directions, thereby enhancing signal connectivity, enhancing design flexibility, and delivering the force detection function.

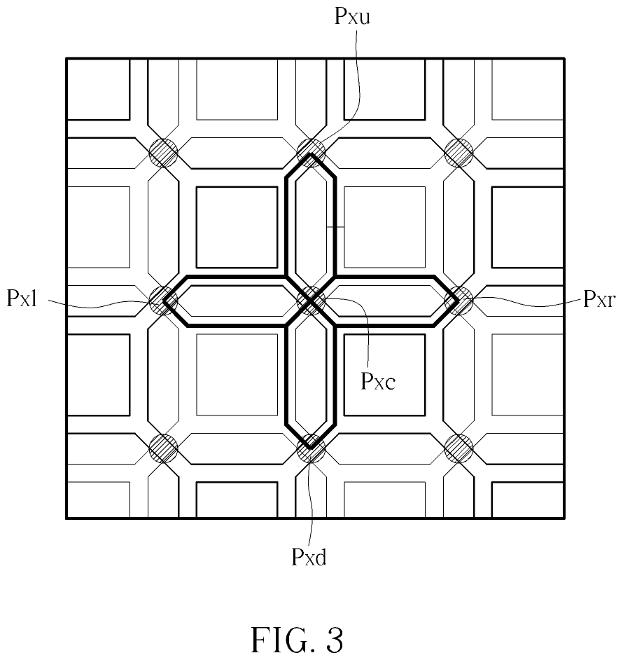

FIG. 3 is a schematic view of the sensing pixels Pxc, Pxu, Pxd, Pxl, Pxr, the first electrode 16 and the second electrode 18. The sensing pixel Pxc may be coupled to the sensing pixels Pxu, Pxd, Pxl, Pxr via the first electrode 16 in the up direction, down direction, left direction and right direction, respectively. Likewise, the sensing pixel Pxc may be coupled to the sensing pixels Pxu, Pxd, Pxl, Pxr via the second electrode 18 in the up direction, down direction, left direction and right direction, respectively. When a force is applied to the sensing pixel Pxc, the electrical parameter generated by the sensing pixel Pxc may be transmitted to the sensing pixels Pxu, Pxd, Pxl, Pxr in the 4 directions. The sensing pixel Pxc may remain connected even if some of the sensing pixels Pxu, Pxd, Pxl, Pxr are removed in the cropping process. For example, if the sensing pixels Pxu, Pxd, Pxl are removed and only the sensing pixel Pxr remains connected to the sensing pixel Pxc, the electrical parameter may be transmitted from the sensing pixel Pxc to the sensing pixel Pxr, and further passed via the sensing pixels adjacent to the sensing pixel Pxr until reaching the sensing pads. As a result, the connectivity of the sensing pixel Pxc is unaffected or less affected by the cropping process.

The piezosensitive sensor 1 may be cropped into a plurality of sensors in a regular shape or in an irregular shape. Each sensor may include 2 sensing pads for reading the electrical parameters generated by the sensor.

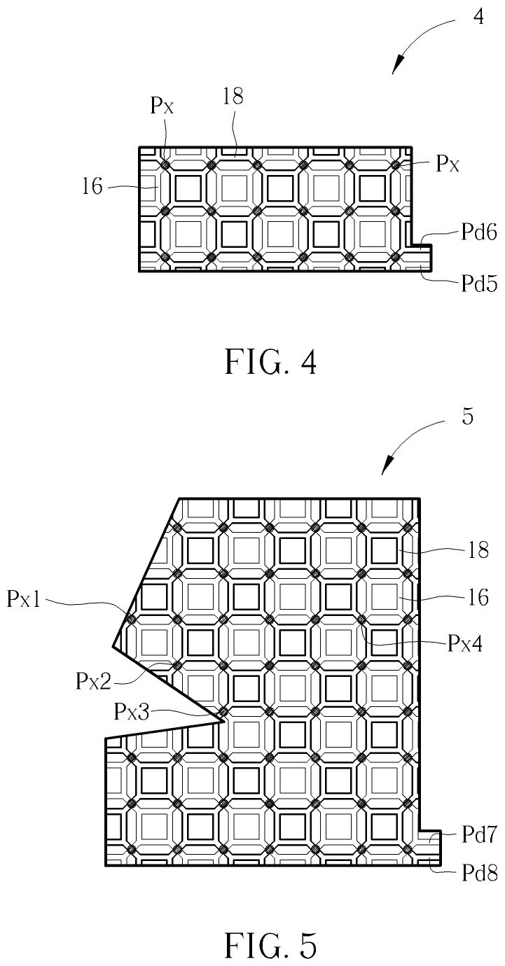

FIG. 4 is schematic view of a cropped piezosensitive sensor 4 according to an embodiment of the invention. The piezosensitive sensor 4 is cropped into a rectangular shape, with a sensing pad Pd5 being configured to read the electrical parameter on the first electrode 16 and a sensing pad Pd6 being configured to read the electrical parameter on the second electrode 18. Sensing pixels Px in the first column may have connectivity in 2 or 3 directions, sensing pixels Px in the second column to the fifth column may have connectivity in 3 or 4 directions, and sensing pixels Px in the sixth column may have connectivity in 2 or 3 directions. In this configuration, all sensing pixels Px may be used to detect a force applied, and electrical parameters may be read from the sensing pads Pd5 and Pd6 to derive a detection result.

FIG. 5 is schematic view of a cropped piezosensitive sensor 5 according to another embodiment of the invention. The piezosensitive sensor 5 is cropped into an irregular shape, with a sensing pad Pd7 being configured to read the electrical parameter on the first electrode 16 and a sensing pad Pd8 being configured to read the electrical parameter on the second electrode 18. Boundary sensing pixels may have less connectivity than central sensing pixels owing to the irregular shape of the piezosensitive sensor 5. For example, a sensing pixel Pxl may have a single connectivity to the right sensing pixel Px, and the electrical parameters of the first electrode 16 and second electrode 18 may only be transmitted via the connection to the right sensing pixel Px; a sensing pixel Px2 may have 2-direction connectivity, and the electrical parameters of the first electrode 16 and second electrode 18 may be transmitted via the connections to the upper and right sensing pixels Px; a sensing pixel Px3 may have 2-direction connectivity, and the electrical parameters of the first electrode 16 and second electrode 18 may be transmitted via the connections to the upper and right sensing pixels Px; and a sensing pixel Px 4 is located in the central position of the piezosensitive sensor 5, and may have 4-direction connectivity, and the electrical parameters of the first electrode 16 and second electrode 18 may be transmitted via the connections to the upper, lower, left and right sensing pixels Px. In this configuration, all sensing pixels Px may be used to detect a force applied, and electrical parameters may be read from the sensing pads Pd7 and Pd8 to derive a detection result.

The piezosensitive sensors 1, 3, 4 employ the meshed structure of the first electrode 16 and the second electrode 18 to enhance signal connectivity between the sensing pixels Px, enhancing design flexibility while delivering the force detection function.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A piezosensitive sensor comprising:
a first substrate;
a second substrate;
a first electrode formed on the first substrate;
a second electrode formed on the second substrate; and
a sensor array comprising a plurality of sensing pixels arranged in rows and columns, each sensing pixel of the plurality of sensing pixels comprising a piezosensitive element formed between the first electrode and the second electrode and configured to generate an electrical parameter dependent upon a force applied thereto, wherein a sensing pixel of the plurality of sensing pixels is coupled to an upper sensing pixel, a lower sensing pixel, a left sensing pixel and a right sensing pixel via the first electrode and the second electrode in an up direction, a down direction, a left direction and a right direction, respectively.

2. The piezosensitive sensor of claim 1, wherein:
the plurality of sensing pixels are coupled to each other via the first electrode and the second electrode.

3. The piezosensitive sensor of claim 1, wherein the first electrode and the second electrode are meshed in structure.

4. The piezosensitive sensor of claim 1, wherein when generating the electrical parameter, electrical parameters of the first electrode and the second electrode are changed to indicate the force being applied to the piezosensitive element.

5. The piezosensitive sensor of claim 4, wherein:
the electrical parameter of the first electrode is output from a segment of the first electrode coupling between two adjacent sensing pixels;
the electrical parameter of the second electrode is output from a segment of the second electrode coupling between the two adjacent sensing pixels; and
the segment of the first electrode and the segment of the second electrode are arranged in parallel and non-overlapping.

6. The piezosensitive sensor of claim 1, wherein the second electrode is criss-crossed with the first electrode.

7. The piezosensitive sensor of claim 1, wherein the piezosensitive sensor is trimmed into a regular shape.

8. The piezosensitive sensor of claim 1, wherein the piezosensitive sensor is trimmed into an irregular shape.

9. The piezosensitive sensor of claim 1, wherein the piezosensitive sensor is trimmed into a plurality of sensors.

10. The piezosensitive sensor of claim 1, further comprising an adhesion arranged between the first electrode and the second electrode.

11. The piezosensitive sensor of claim 1, wherein the piezosensitive element is made of a piezoelectric material.

12. The piezosensitive sensor of claim 1, wherein the piezosensitive element is made of a piezoresistive material.

13. The piezosensitive sensor of claim 1, wherein the piezosensitive element is made of a piezo-capacitive material.

14. The piezosensitive sensor of claim 1, wherein the first electrode is a top electrode and the second electrode is a bottom electrode.

15. The piezosensitive sensor of claim 1, wherein the piezosensitive element is in contact with the first electrode and the second electrode.
